(19) United States
(12) Patent Application Publication
(10) Pub. No.: US 2016/0066429 A1
(43) Pub. Date: Mar. 3, 2016

(54) FLEX-RIGID WIRING BOARD

(71) Applicant: IBIDEN CO., LTD., Ogaki (JP)

(72) Inventors: Hirotaka TANIGUCHI, Ogaki (JP); Dongdong WANG, Ogaki (JP); Michimasa TAKAHASHI, Ogaki (JP)

(73) Assignee: IBIDEN CO., LTD., Ogaki (JP)

(21) Appl. No.: 14/837,143

(22) Filed: Aug. 27, 2015

(30) Foreign Application Priority Data
Aug. 27, 2014 (JP) 2014-172947

(51) Int. Cl. H05K 1/18; H05K 1/14

(52) U.S. Cl. CPC H05K 1/189; H05K 1/185; H05K 1/147

(57) ABSTRACT

A flex-rigid wiring board includes a flexible base material structure, a rigid base material structure extending from opposite ends of the flexible base material structure, an electronic component embedded in the rigid base material structure, a first buildup layer laminated on first surfaces of the flexible base material structure and rigid base material structure and having an exposing portion exposing the flexible base material structure, and a second buildup layer laminated on second surfaces of the flexible base material structure and rigid base material structure and having an exposing portion exposing the flexible base material structure. The first and second buildup layers are formed such that the flexible base material structure exposed by the exposing portions of the first and second buildup layers forms a bendable portion and that the rigid base material structure and the first and second buildup layers form non-bendable portions connected to the bendable portion.

### CROSS-REFERENCE TO RELATED APPLICATIONS

The present application is based upon and claims the benefit of priority to Japanese Patent Application No. 2014-172947, filed Aug. 27, 2014, the entire contents of which are incorporated herein by reference.

### BACKGROUND OF THE INVENTION

1. Field of the Invention

The present invention relates to a flex-rigid wiring board in which a flexible portion that is bendable is connected to a non-bendable rigid portion having a built-in electronic component.

2. Description of Background Art

Japanese Unexamined Patent Application Publication No. 2012-134490 describes a flexible wiring board. The entire contents of this publication are incorporated herein by reference.

### SUMMARY OF THE INVENTION

According to one aspect of the present invention, a flex-rigid wiring board includes a flexible base material structure, a rigid base material structure extending from opposite ends of the flexible base material structure, an electronic component embedded in the rigid base material structure, a first buildup layer laminated on first surfaces of the flexible base material structure and rigid base material structure and having an exposing portion exposing the first surface of the flexible base material structure, and a second buildup layer laminated on second surfaces of the flexible base material structure and rigid base material structure and having an exposing portion exposing the second surface of the flexible base material structure. The first and second buildup layers are formed such that the flexible base material structure exposed by the exposing portions of the first and second buildup layers forms a bendable portion and that the rigid base material structure and the first and second buildup layers form non-bendable portions connected to the bendable portion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a flex-rigid wiring board according to a first embodiment of the invention;

FIG. 2 is a plan view of the flex-rigid wiring board when viewed from a first side;

FIG. 3 illustrates the layout of interconnections connecting a first pad with a flexible portion;

FIG. 4 is a side view of a semiconductor module;

FIG. 5A, 5B, and 5C illustrate processes in manufacturing the flex-rigid wiring board;

FIG. 6A and 6B illustrate processes in manufacturing the flex-rigid wiring board;

FIG. 7A, 7B, and 7C illustrate processes in manufacturing the flex-rigid wiring board;

FIG. 8A and 8B illustrate processes in manufacturing the flex-rigid wiring board;

FIG. 9A and 9B illustrate processes in manufacturing the flex-rigid wiring board;

FIG. 10 illustrates a process in manufacturing the flex-rigid wiring board;

FIG. 11 illustrates a process in manufacturing the flex-rigid wiring board;

FIG. 12 illustrates a process in manufacturing the flex-rigid wiring board;

FIG. 13 illustrates a process in manufacturing the flex-rigid wiring board;

FIG. 14 is a side view of a flex-rigid wiring board according to an example modification thereto;

FIG. 15 is a cross-sectional view of a flex-rigid wiring board according to an example modification thereto;

FIG. 16 is a cross-sectional view of a flex-rigid wiring board according to an example modification thereto;

FIG. 17 is a cross-sectional view of a flex-rigid wiring board according to an example modification thereto;

FIG. 18 is a cross-sectional view of a flex-rigid wiring board according to an example modification thereto;

FIG. 19 is a cross-sectional view of a flex-rigid wiring board according to an example modification thereto; and

FIG. 20 is a cross-sectional view of a flex-rigid wiring board according to an example modification thereto.

### DETAILED DESCRIPTION OF THE EMBODIMENTS

The embodiments will now be described with reference to the accompanying drawings, wherein like reference numerals designate corresponding or identical elements throughout the various drawings.

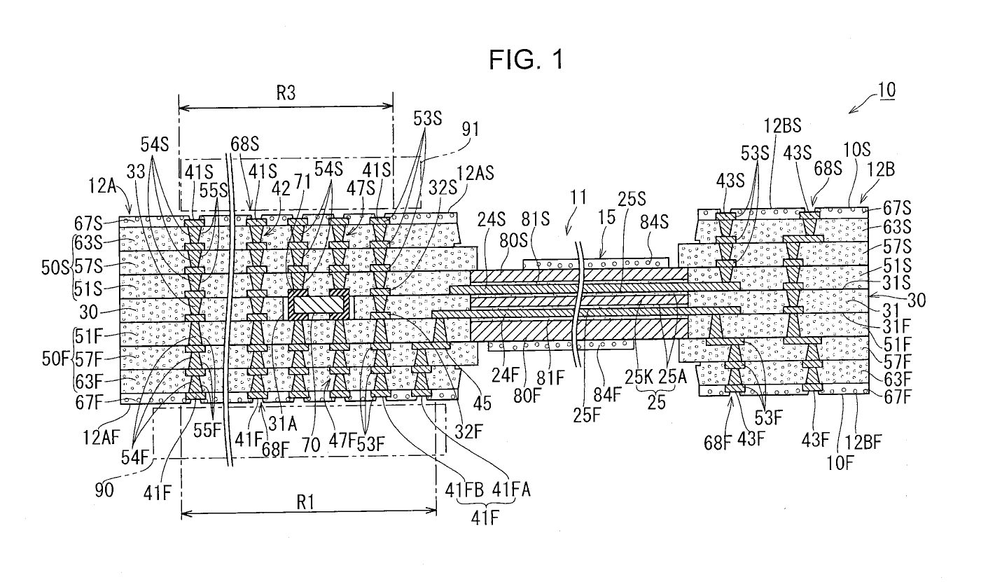

A first embodiment of the invention is described below on the basis of FIG. 1 to FIG. 13. A flex-rigid wiring board 10 according to the first embodiment is provided with a flexible base material 15, and rigid base materials (30, 30) which sandwich the flexible base material 15 when viewed from the thickness direction. Buildup layers (50F, 50S) are laminated on the front and rear surfaces of the flexible base material 15 and the rigid base materials (30, 30).

The buildup layers (50F, 50S) cover both side portions of the flexible base material 15 and expose the center portion of the flexible base material 15. The exposed portions of the flexible base material 15 form a flexible portion 11 that is elastically deformable, and a primary rigid portion (12A) and a secondary rigid portion (12B) are formed on both sides of the flexible portion 11. The primary rigid portion (12A) includes the rigid base material 30 and the buildup layers (50F, 50S). The primary rigid portion (12A) and the secondary rigid portion (12B) constitute the rigid portion in an embodiment of the invention and is connected to be able to fold and bend via the flexible portion 11. Both side portions of the flexible base material 15 slightly enter the primary rigid portion (12A) and the secondary rigid portion (12B).

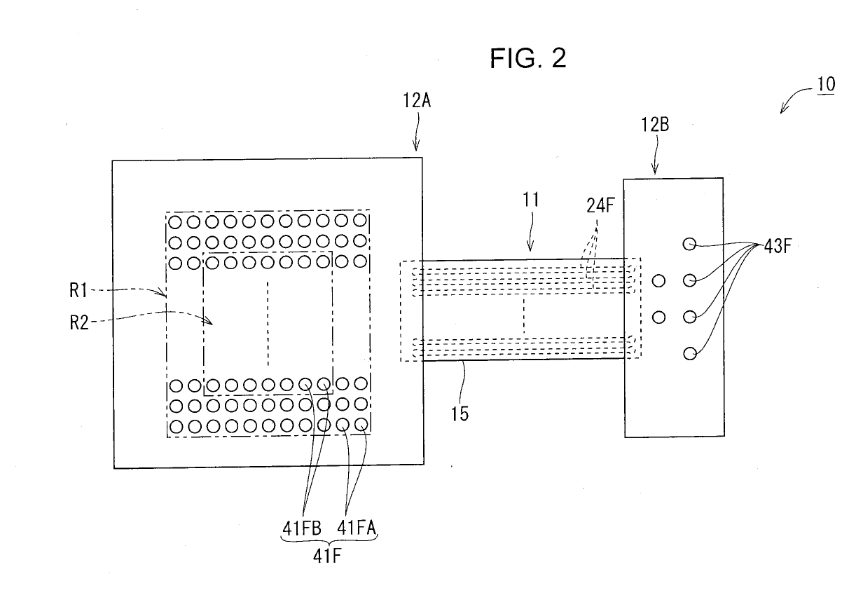

The flexible base material 15 may be provided with, for example, a flexible intermediate base material 25 formed by laminating adhesive layers (25A) on both surfaces of a resin film (25K) such as a polyimide film, a first interconnect layer (24F) formed on a first surface (25F) which is one of the front or rear surfaces of the flexible intermediate base material 25, and a second interconnect layer (24S) formed on a second surface (25S) which is the other of the front or rear surface of the flexible intermediate base material 25. First interconnect layer (24F) and second interconnect layers(24S) are formed along a straight line to connect the primary rigid portion (12A) and the secondary rigid portion (12B). In FIG. 2 only the first interconnect layer (24F) is illustrated. The first interconnect layer (24F) and the second interconnect layer (24S) may be connected by way of vias passing through the flexible intermediate base material 25.

An adhesive layer (81F) is formed on the first interconnect layer (24F) and a coverlay (coating layer, 80F) formed on the adhesive layer (81F). The coverlay (80F) is then covered with a solder resist layer (84F). An adhesive layer (81S) is formed on the second interconnect layer (24S) and a coverlay (coating layer, 80S) formed on the adhesive layer (81S). The coverlay (80S) is then covered with a solder resist layer (84S). The coverlays (80F, 80S) are composed of an insulating film such as polyimide.

The rigid base material 30 includes a rigid intermediate base material 31, a first intermediate conductive layer (32F) formed on a first surface (31F) which is one of the front or rear surfaces of the rigid intermediate base material 31, and a second intermediate conductive layer (32S) formed on a second surface (31S) which is the other of the front or rear surface of the rigid intermediate base material 31. The first intermediate conductive layer (32F) and the second intermediate conductive layer (32S) may be connected by way of a conductive via 33 passing through the rigid intermediate base material 31. The rigid intermediate base material 31 may be composed of an insulating material, such as a prepreg (a B-stage resin sheet formed by soaking a core in resin).

An electronic component 70 including multiple external electrodes 71 on both the front and rear surfaces thereof is embedded in the rigid base material 30 in the primary rigid portion (12A). In concrete terms, the electronic component 70 is housed in an opening (31A) in the rigid intermediate base material 31. The first intermediate conductive layer (32F) and the second intermediate conductive layer (32S) are also laminated onto portions of the rigid intermediate base material 31 except the opening (31A). Namely, the opening 31A is formed slightly larger than the electronic component 70 and the gap between the opening 31A and electronic component 70 is filled with the insulating material making up the rigid intermediate base material 31 or the insulating material making up the later-described insulating buildup layer (51F, 51S).

Insulating buildup layers (51F, 57F, 63F), and conductive buildup layers (53F) are alternately laminated on the first intermediate conductive layer (32F). Insulating buildup layers (51S, 57S, 63S), and conductive buildup layers (53S) are also alternately laminated on the second intermediate conductive layer (32S). The insulating buildup layers (51F, 57F, 63F) and the conductive buildup layers (53F) thus form the above-described buildup layer (50F), and the insulating buildup layers (51S, 57S, 63S) and the conductive buildup layers (53S) thus form the above-described buildup layer (50S).

The conductive buildup layers (53F, 53S), i.e., the outermost conductive buildup layers (53F, 53S), which are laminated onto the insulating buildup layers (63F, 63S) have solder resist layers (67F, 67S) laminated thereon. The solder resist layer (67F) constitutes a first surface (10F) which is one of the front or rear surfaces of the flex-rigid wiring board 10, while the solder resist layer (67S) constitutes a second surface (10S) which is the other of the front or rear surface of the flex-rigid wiring board 10.

Multiple openings (68F) is formed in the solder resist layer (67F) on the first surface (10F) of the flex-rigid wiring board 10 exposing a portion of the outermost conductive buildup layer (53F). The openings (68F) forms multiple first pads (41F) which expose a portion of the outermost conductive buildup layer (53F) in a first surface (12AF) which is one of the front or rear surfaces of the primary rigid portion (12A) for mounting an electronic component. The openings (68F) also form multiple mounting pads (43F) which expose a portion of the outermost conductive buildup layer (53F) in a first surface (12BF) which is one of the front or rear surfaces of the secondary rigid portion (12B). Multiple openings (68S) is formed in the solder resist layer (67S) on the second surface (10S) of the flex-rigid wiring board 10 exposing a portion of the outermost conductive buildup layer (53S). The openings (68S) forms multiple second pads (41S) which expose a portion of the outermost conductive buildup layer (53S) in a second surface (12AS) which is the other of the front or rear surfaces of the primary rigid portion (12A) for mounting an electronic component. The openings (68S) also form multiple mounting pads (43S) which expose a portion of the outermost conductive buildup layer (53S) in a second surface (12BS) which is the other of the front or rear surfaces of the secondary rigid portion (12B).

As illustrated in FIG. 2, the first pads (41F) and second pads (41S) formed on the front and rear surfaces of the primary rigid portion (12A) are arrayed in a grid (refer to FIG. 2, only the first pads (41F) are depicted). The pitch of the first pads (41F) and the pitch of the second pads (41S) are 250 to 500 μm. Here, the primary rigid portion (12A) and the secondary rigid portion (12B) enter both sides of the flexible base material 15 as above described (both sides of the flexible base material 15 are depicted with dotted lines in FIG. 2). When the primary rigid portion (12A) is viewed from the thickness direction, the end of the flexible base material 15 near the primary rigid portion (12A) is positioned outside an array region (R1) where the first pads (41F) are disposed.

As illustrated in FIG. 1, a portion of the first pads (41F) on the first surface (10F) of the flex-rigid wiring board 10 are connected to the secondary rigid portion (12B) via the first interconnect layer (24F) in the flexible base material 15. More specifically, as illustrated in FIG. 1 and FIG. 2, outer pads (41FA) that are the first pads (41F) arrayed surrounding outside the array region (R1) are connected to the secondary rigid portion (12B), and inner pads (41FB) that are the first pads (41F) arrayed inward of the outer pads (41FA) in the array region (R1) are connected to the electronic component 70 embedded in the primary rigid portion (12A) or to the second surface (12AS) of the primary rigid portion (12A). In this embodiment, the array region (R2) where the inner pads (41FB) are disposed (refer to FIG. 2) coincides with an array region (R3) where the second pads (41S) are disposed (refer to FIG. 1). In the example illustrated in FIG. 2, both the array region (R1) where the first pads (41F) are arrayed, and the inner array region (R2) where the inner pads (41FB) are arrayed are squares.

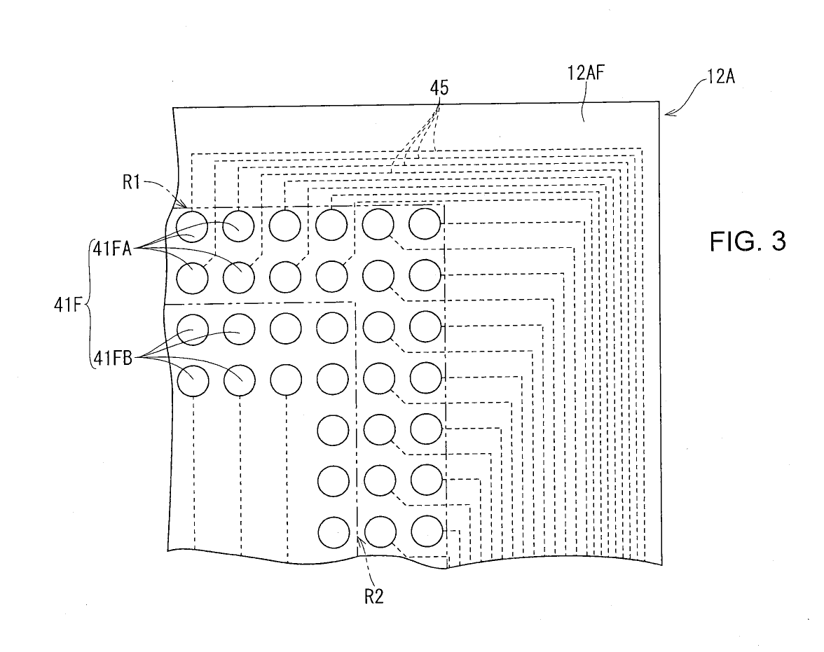

As illustrated in FIG. 1, the interconnect 45 connecting between the outer pads (41FA) and the first interconnect layer (24F) is constituted by an interconnect pattern formed on a portion of the conductive buildup layer (53F). As illustrated in FIG. 3, the interconnect 45 is disposed outside of the inner region (R2) where the inner pads (41FB) are disposed and do not pass between inner pads (41FB).

A portion of the inner pads (41FB) and the outer electrodes 71 of the electronic component 70 (more specifically, the outer electrodes 71 on the first surface (12AF)) are connected by way of first stacked vias (47F). The first stacked vias (47F) are multiple conductive vias (54F) laminated overlapping along a straight line passing through the insulating buildup layers (51F, 57F, 63F).

A portion of the first pads (41F) and a portion of the second pads (41S) are also connected by way of full stacked vias 42 through the primary rigid portion (12A). The full stack via 42 is formed by laminating the conductive via 33 through the rigid base material 30, the conductive vias (54F) through the insulating buildup layer (51F, 57F, 63F), and the conductive vias (54S) through the insulating buildup layer's (51S, 57S, 63S) to overlap along a straight line.

Further, as illustrated in FIG. 1, a portion of the second pads (41S) is connected to the external electrodes 71 on the electronic component 70 (more specifically, the external electrodes 71 on the second surface (12AS)) by way of the second stacked vias (47S). The second stacked vias (47S) are multiple conductive vias (54S) laminated overlapping along a straight line passing through the insulating buildup layers (51S, 57S, 63S).

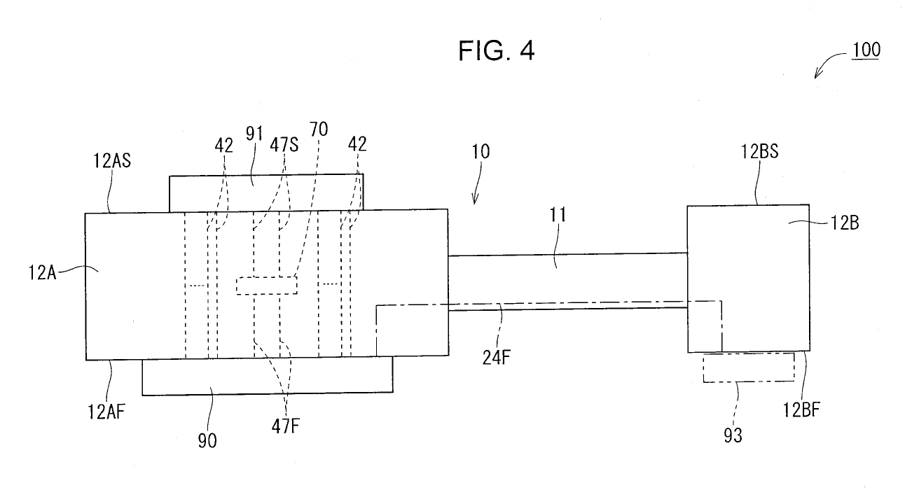

A mounted component may be an active component 90 mounted on the first surface (12AF) of the primary rigid portion (12A). The first pads (41F) are connected to this active component. A mounted component may be a passive component 91 mounted on the second surface (12AS) of the primary rigid portion (12A). The second pads (41S) are connected to this passive component. Further, the flex-rigid wiring board 10, the active component 90, and the passive component 91 form the semiconductor module 100 illustrated in FIG. 4. The active component 90 is connected to the passive component 91 via the inner pads (41FB) among the first pads (41F) (refer to FIG. 1), and is connected to the secondary rigid portion (12B) via the outer pads (41FA) (refer to FIG. 1). The active component 90 is also connected to the mounting pads (43F, 43S) by way of an interconnect (not shown) formed inside the secondary rigid portion (12B). An electronic component 93 such as a connector may be mounted on the mounting pads (43F, 43S). Further, examples of an active component 90 include semiconductor devices and integrated circuits, however, in the first embodiment it is an integrated circuit (IC). Examples of a passive component 91 include a chip capacitor, an inductor, a resistor, a piezoelectric element, and the like.

The structure of the flex-rigid wiring board 10 is as above described.

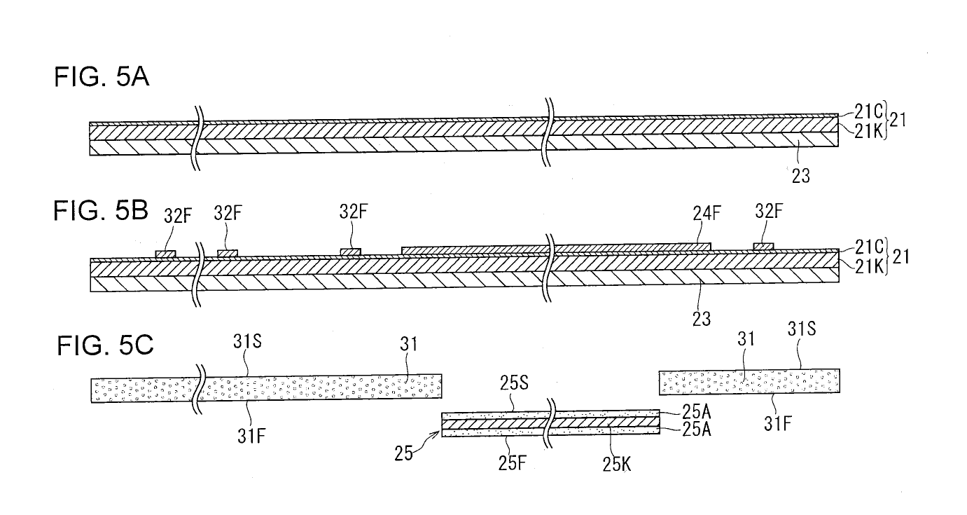

A method of manufacturing the flex-rigid wiring board 10 is described on the basis of FIG. 5A to FIG. 13.

A flex-rigid wiring board 10 may be manufactured as follows.

(1) As illustrated in FIG. 5A, a copper foil (21C) is laminated on the upper surface of an insulating base material (21K) to form a carrier 21, and the carrier 21 is laminated onto a support substrate 23. Although not depicted, an adhesive layer is formed between the insulating base material (21K) and the copper foil (21C) as well as between the carrier 21 (the insulating base material, 21K) and the support substrate 23. The adhesive strength between the insulating base material (21K) and the copper foil (21C) is weaker than the adhesive strength between the carrier 21 (insulating base material, 21K) and the support substrate 23

(2) The surface of the copper foil (21C) is masked with resist and electroplated to form a predetermined pattern of a first interconnect layer (24F) and first intermediate conductive layers (32F) thereon (refer to FIG. 5B). At this point, the first intermediate conductive layers (32F) are disposed at both ends on the carrier 21, and the first interconnect layer (24F) is disposed closer to the center on the carrier 21.

(3) As illustrated in FIG. 5C, a flexible intermediate base material 25 is prepared by laminating an adhesive layer (25A) on both surfaces of a resin film (25K), as gaps are formed in rigid intermediate base materials (31, 31) to accommodate the flexible intermediate base material 25. Here the thicknesses of the flexible intermediate base material 25 and the rigid intermediate base material 31 are substantially identical.

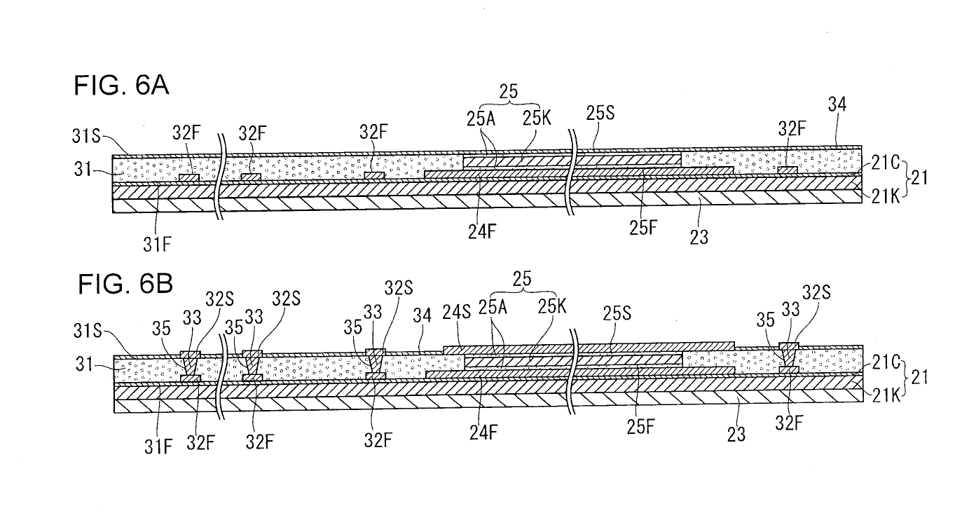

(4) As illustrated in FIG. 6A, the first surface (25F) of the flexible intermediate base material 25 and the first surface (31F) of the rigid intermediate base materials (31, 31) are laminated onto the carrier 21. A copper foil 34 is then laminated onto the second surfaces (31S, 31S) of the rigid intermediate base materials (31, 31) and the second surface (25S) of the flexible intermediate base material 25 and pressed. At this point the flexible intermediate base material 25 is disposed on the first interconnect layer (24F), and the rigid intermediate base materials (31, 31) positioned horizontally to sandwich the flexible intermediate base material 25 therebetween. Additionally, the first interconnect layer (24F) and the first intermediate conductive layers (32F) are sunken into the flexible intermediate base material 25 and the rigid intermediate base materials (31, 31).

(5) Openings 35 are laser machined into the rigid intermediate base materials 31, 31 and the copper foil 34 for exposing the first intermediate conductive layers (32F). As illustrated in FIG. 6B, a second interconnect layer (24S) and a second intermediate conductive layer (32S) are formed on the unmasked portions of the rigid intermediate base material with no plated resist through a series of electroless plating, electroplating of a resist, and electroplating; conductive vias 33 are also formed in the openings 35. Second interconnect layer (24S) is formed along a line connecting the rigid intermediate base materials (31, 31) (refer to FIG. 2); both ends of the second interconnect layer (24S) are positioned on the second surface (31S) of the rigid intermediate base materials (31, 31).

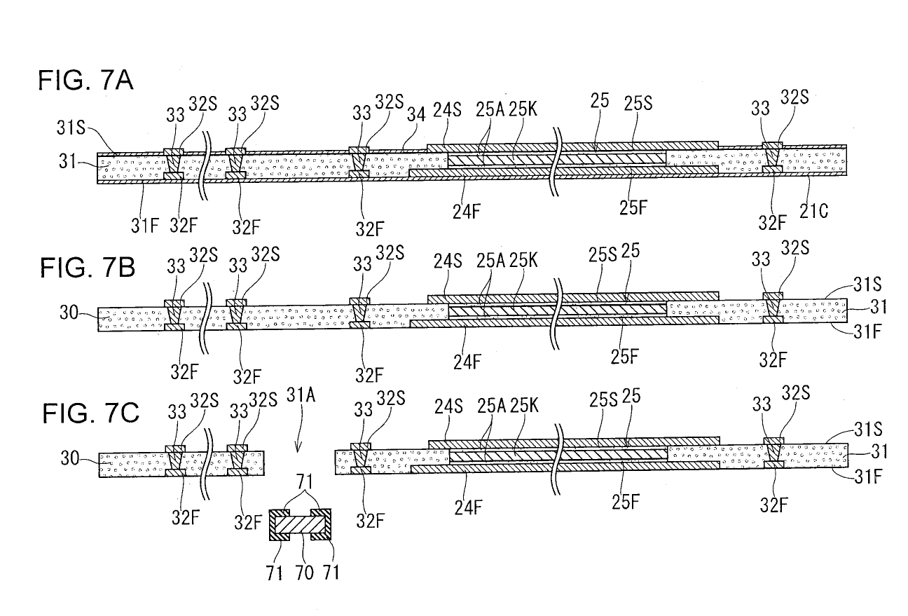

(6) As illustrated in FIG. 7A, the insulating base material (21K) on the carrier 21 and the support substrate 23 are peeled off to expose the copper foil (21C) on the first surface (31F) of the rigid intermediate base material 31.

(7) As illustrated in FIG. 7B, the copper foil (21C) and the copper foil 34 are removed by etching. At this point, the second interconnect layer (24S) and the second intermediate conductive layer (32S) protrude from the second surface (25S) of the flexible intermediate base material 25 and the second surface (31S) of the rigid intermediate base material 31, while the first interconnect layer (24F) and the first intermediate conductive layer (32F) are buried inside the flexible intermediate base material 25 and the rigid intermediate base material 31.

(8) As illustrated in FIG. 7C, an electronic component 70 is prepared, and an opening (31A) large enough to accommodate the electronic component 70 is formed in the rigid intermediate base material 31. Namely, the opening (31A) is formed slightly larger than the electronic component 70.

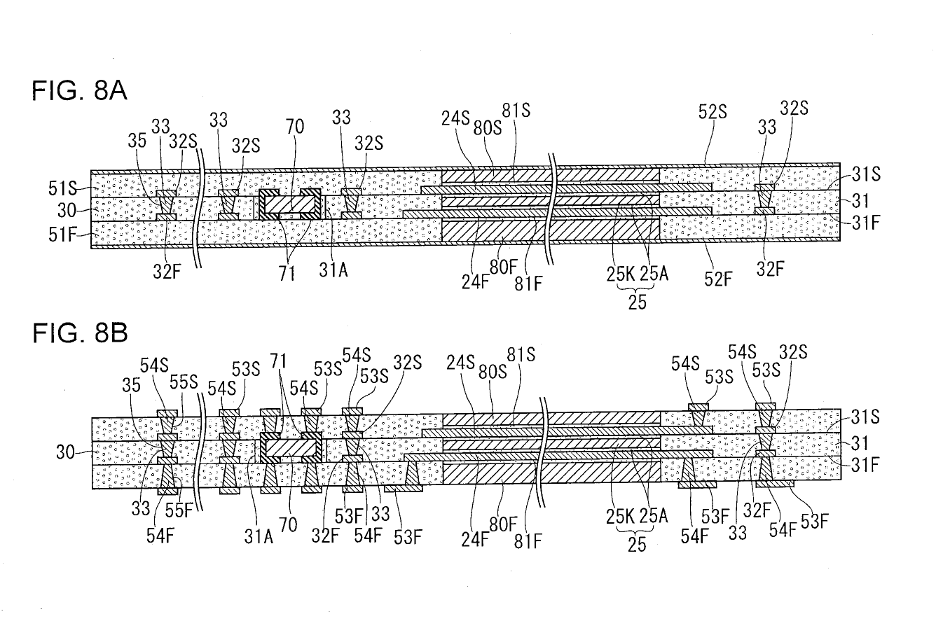

(9) A coverlay (80F) is laminated onto the middle portion of the first interconnect layer (24F) over the adhesive layer (81F); another coverlay (80S) is laminated onto the middle portion of the second interconnect layer (24S) over the adhesive layer (81S). The electronic component 70 is inserted into the opening (31A) in the rigid intermediate base material 31, and an insulating buildup layer (51F) composed of a prepreg is laminated onto the first surface (31F) of the rigid intermediate base material 31 and onto both end portions of the first interconnect layer (24F). The insulating buildup layer (51S) is also laminated onto the second surface (31S) of the rigid intermediate base material 31 and onto both end portions of the second interconnect layer (24S). Copper foils (52F, 52S) are laminated over the coverlays (80F, 80S) and the insulating buildup layer (51F, 51S) (refer to FIG. 8A). At this point the gap between the opening (31A) and the electronic component 70 is filled with the insulating material making up the rigid intermediate base material 31 or the insulating material making up the insulating buildup layers (51F, 51S). The upper outer surfaces of the external electrodes 71 on the electronic component 70 near the second surface (31S) are disposed substantially flush with the upper outer surface of the second intermediate conductive layer (32S).

(10) Openings (55F, 55S) are laser machined into the insulating buildup layer (51F) and the insulating buildup layer (51S) respectively. The openings (55F, 55S) expose the first interconnect layer (24F) and first intermediate conductive layers (32F), and the second interconnect layers (24S) and the second intermediate conductive layer (32S) respectively. Conductive vias (54F, 54S) are also formed in the conductive buildup layers (53F, 53S) using the same processes in processes (5) through (8) (refer to FIG. 8B).

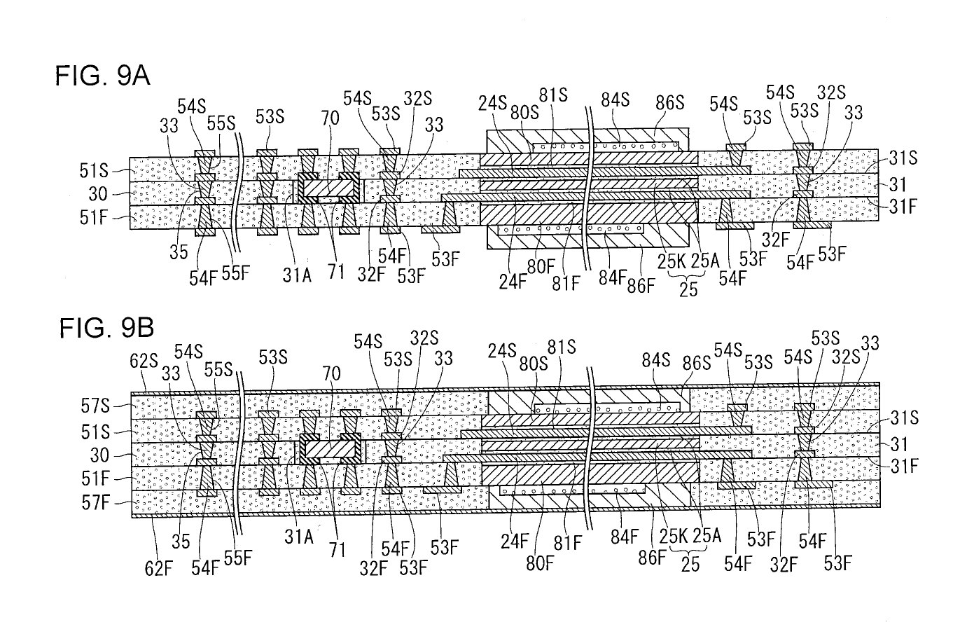

(11) As illustrated in FIG. 9A, a solder resist layer (84F) is formed on the coverlay (80F), and a separation layer (86F) is formed on the solder resist layer (84F). A solder resist layer (84S) is also formed on the coverlay (80S), and a separation layer (86S) is formed on the solder resist layer (84S).

(12) As illustrated in FIG. 9B, the insulating buildup layer (57F) is formed on both sides of the solder resist layer (84F) and the separation layer (86F) in the horizontal direction. The insulating buildup layer (57S) is formed on both sides of the solder resist layer (84S) and the separation layer (86S) in the horizontal direction. Copper foils (62F, 62S) are laminated onto the insulating buildup layers (57F, 57S).

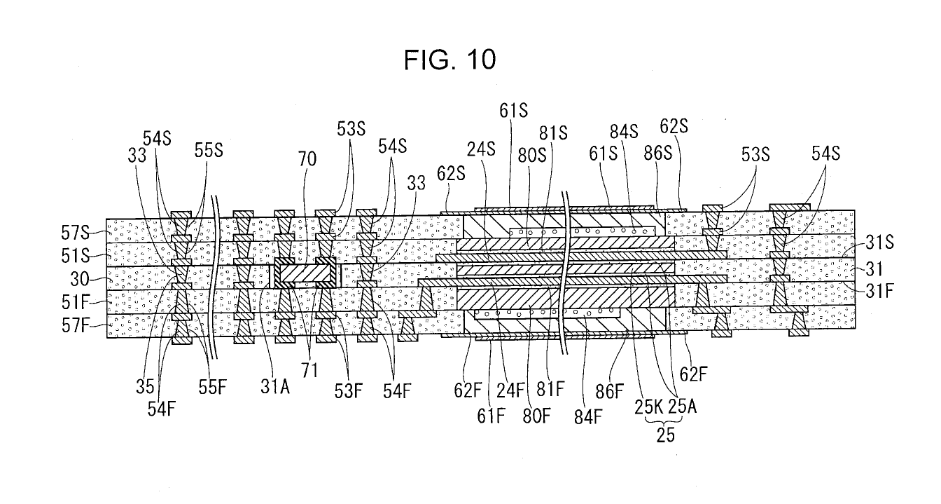

(13) The openings (55F, 55S) are formed in the insulating buildup layers (57F, 57S) using processes identical to those in (10) above; conductive vias (54F, 54S) are also formed in the insulating buildup layers (57F, 57S), and the conductive buildup layers (53F, 53S) formed on the insulating buildup layers (57F, 57S). Separation conductors (61F, 61S) are formed on the separation layers (86F, 86S) exposing the copper foils (62F, 62S) at the ends thereof (refer to FIG. 10).

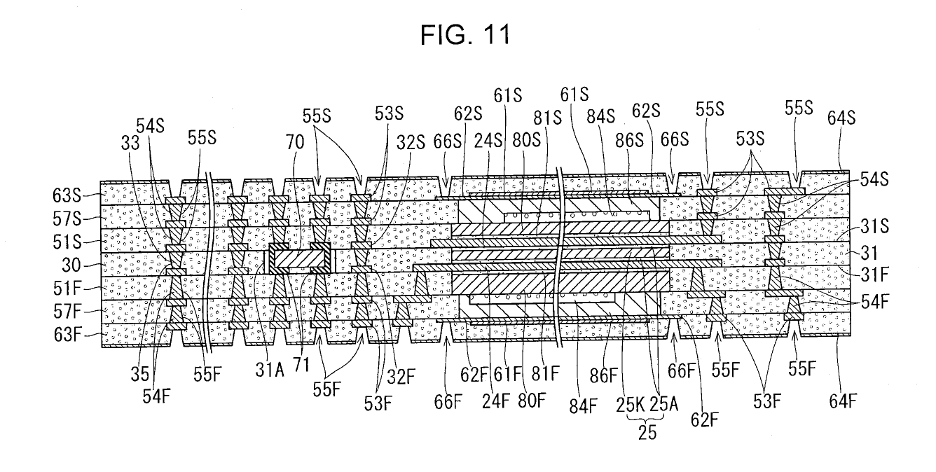

(14) The insulating buildup layers (63F, 63S) and copper foils (64F, 64S) are laminated onto the conductive buildup layers (53F, 53S) and the separation conductors (61F, 61S). The openings (55F, 55S) are laser machined into the insulating buildup layers (63F, 63S) exposing the conductive buildup layers (53F, 53S); additionally, slits (66F, 66S) are laser machined into the insulating buildup layers (63F, 63F) exposing the copper foils (62F, 62S) surrounding the separation conductors (61F, 61S) (refer to FIG. 11).

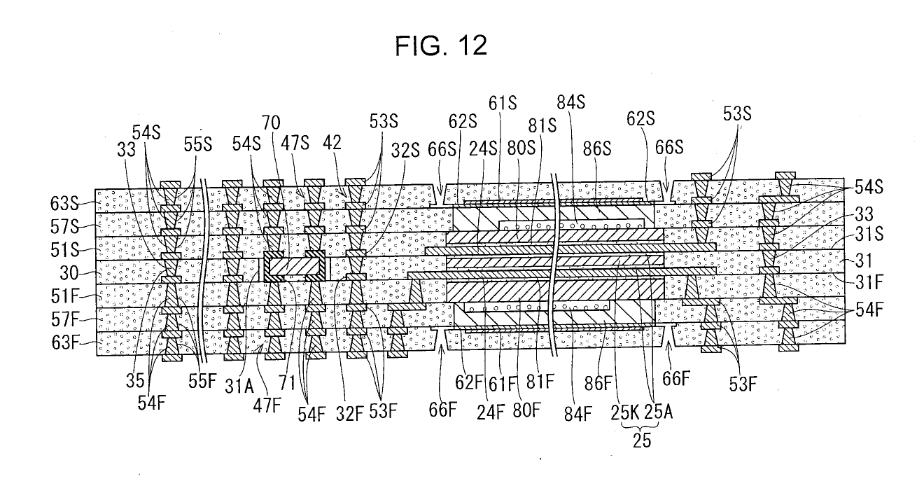

(15) The conductive vias (54F, 54S) are formed passing through the insulating buildup layers (63F, 63S), and the conductive buildup layers (53F, 53S) are formed on the insulating buildup layers (63F, 63S) using processes identical to those in (10) above. The copper foils (62F, 62S) projecting outside the separation layers (86F, 86S) are removed from the bottom of the slits (66F, 66S) (refer to FIG. 12). At this point, the conductive vias 33 located on one side in the horizontal direction relative to the flexible intermediate base material 25 (in the example illustrated in FIG. 12, on the left side) overlap with and connect to multiple conductive vias (54F) and multiple conductive vias (54S) in the thickness direction. These conductive vias (33, 54F, 54S) thusly form a full stacked via 42. Additionally, multiple conductive vias (54F) overlap and connect with each other to form first stacked vias (47F) on the first surface (31F) of the rigid intermediate base material 31 over the electronic component 70, while multiple conductive vias (54S) overlap and connect with each other to form second stacked vias (47S) on the second surface (31S) of the rigid intermediate base material 31 over the electronic component 70.

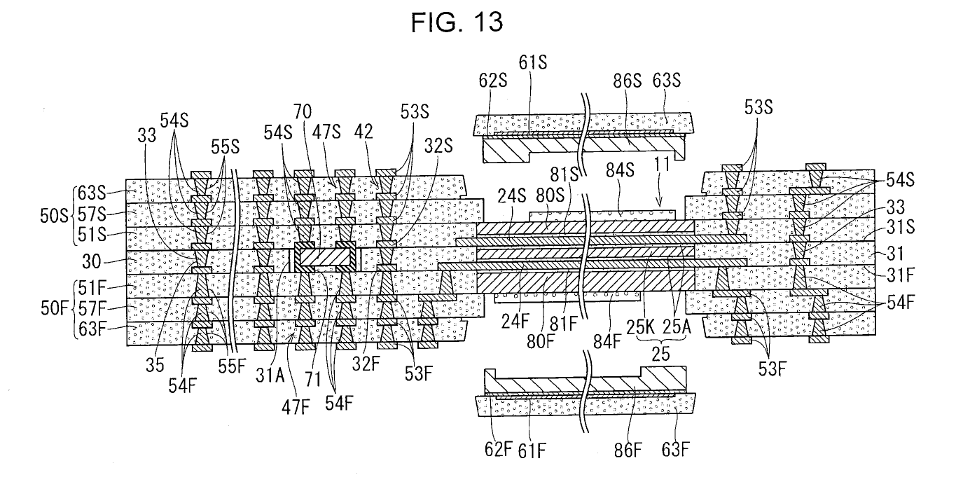

(16) As illustrated in FIG. 13, the separation layers (86F, 86S) on the solder resist layers (84F, 84S), and the insulating buildup layer (63S, 63F) inside the slits (66F, 66S) are removed. At this point a portion of the flexible base material 15 carrying the flexible intermediate base material 25, the coverlays (80F, 80S), and the solder resist layer (84F, 84S) is exposed, with the exposed portion forming the flexible portion 11.

(17) The solder resist layers (67F, 67S) (refer to FIG. 1) are formed on the insulating buildup layers (63F, 63S), creating the primary rigid portion (12A) containing the stacked via 42 on one side relative to the flexible portion 11 in the horizontal direction, and creating the secondary rigid portion (12B) opposite the primary rigid portion (12A) such that the flexible portion 11 is sandwiched between the primary rigid portion (12A) and the secondary rigid portion (12B). Openings (68F, 68S) are formed in the solder resist layers (67F, 67S) exposing a portion of the outward most conductive buildup layers (53F, 53S) on the primary rigid portion (12A) which serve as the first pads (41F) and the second pads (41S), and exposing a portion of the outward most conductive buildup layers (53F, 53S) on the secondary rigid portion (12B) which serve as the mounting pads (43F, 43S). Herewith, the production of the flex-rigid wiring board 10 illustrated in FIG. 1 is complete.

Here ends the description of the structure and method of production for a flex-rigid wiring board 10 according to the first embodiment. Next, the functional effects of the flex-rigid wiring board 10 are described.

In the flex-rigid wiring board 10 according to the first embodiment, the first stacked vias (47F) connect the first pads (41F) and the electronic component 70; additionally, when the primary rigid portion (12A) is viewed from the thickness direction, the flexible base material 15 is positioned outside the array region (R1) hosting the first pads (41F). Therefore, it is possible to suppress the influence of an expanding and contracting flexible base material 15 when creating the first stacked vias (47F), as well as to provide high-density connections between a mounted component (active component 90) mounted on the first pads (41F) and the electronic component 70. Additionally, because the electronic component 70 is embedded in the rigid base material 30, the space on the sides of the flexible base material 15 may be effectively used to make the primary rigid portion (12A) thinner.

In the flex-rigid wiring board 10 according to the first embodiment, the second stacked vias (47S) connect the second pads (41S) and the electronic component 70; additionally, when the primary rigid portion (12A) is viewed from the thickness direction, the flexible base material 15 is positioned outside the array region (R2) hosting the second pads (41S). Therefore, it is possible to provide high-density connections between the second pads (41S) and the electronic component 70, similarly to the first pads (41F).

Furthermore, because the interconnect 45 connecting the outer pads (41FA) and the secondary rigid portion (12B) does not pass between inner pads (41FB) in the flex-rigid wiring board 10 according to the first embodiment, high-density connections may be provided between the active component 90 mounted on the first pads (41F) and the electronic component 70, and between the active component 90 and the passive component 91 mounted on the second pads (41S). Examples of the electronic component 70 include an active component such as a semiconductor device and an integrated circuit and a passive component such as a chip capacitor, an inductor, a resistor and a piezoelectric element.

### OTHER EMBODIMENTS

The present invention is not limited to the above described embodiment. For instance, the following working examples are included within the technical scope of the present invention. Moreover, the present invention may be modified in various other ways besides the modifications listed below insofar as the modifications are within the spirit and scope thereof.

1) In the first embodiment, the array region (R1) where the first pads (41F) are arrayed, and the inner region (R2) where the inner pads (41FB) are arrayed, and the array region (R3) of the second pads (41S) are squares. However, the shapes of the regions (R1, R2, R3) are not particularly limited thereto. For instance, the regions (R1, R2, R3) may be circular or cross-shaped. The array region (R1), the inner region (R2), and the array region (R3) may each be different shapes.

(2) In the first embodiment, the flexible intermediate base material 25 and the rigid intermediate base material 31 are substantially identical thicknesses. However, for instance, the flexible intermediate base material 25 may be thinner than the rigid intermediate base material 31. With a thinner flexible intermediate base material 25, a desired resin may be used to fill the gap between the flexible intermediate base material 25 and the insulating buildup layers (51F, 51S). For example, the resin that oozes out from the insulating buildup layers (51F, 51S), or a pre-inserted resin used for height adjustments during production may be used to fill the gap.

(3) In the example described for the first embodiment, the flexible intermediate base material 25 is formed with a substantially uniform width; however the section constituting the flexible portion 11 (the exposed section) may be wider.

(4) The first embodiment may be modified such that the second pads (41S) are excluded from the primary rigid portion (12A).

(5) The first embodiment may be modified such that the second pads (41S) are connected to only the electronic component 70, or to only the first pads (41F).

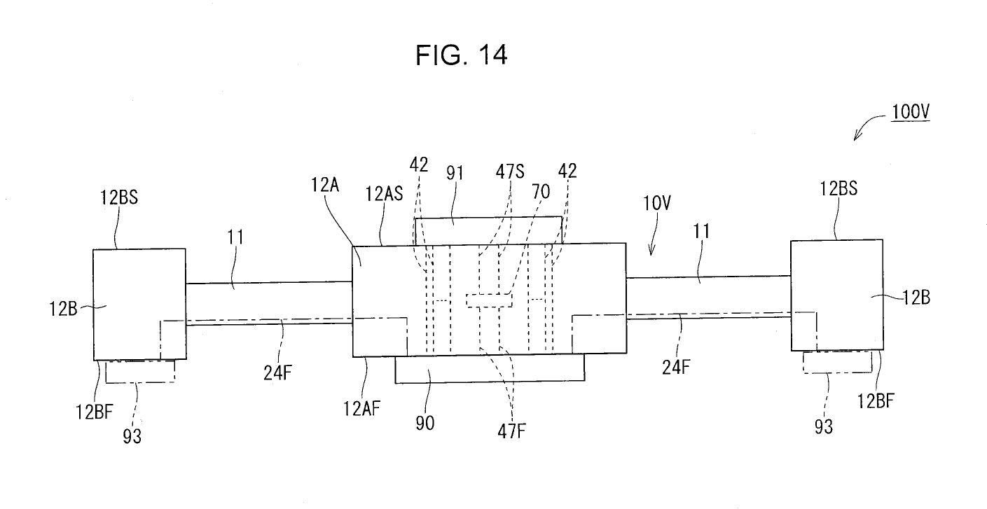

(6) One of each of the flexible portion 11 and the secondary rigid portion (12B) are provided next to the primary rigid portion (12A) in the flex-rigid wiring board 10 in the first embodiment. However, for instance, as exemplified by the flex-rigid wiring board 10V and the semiconductor module 100V illustrated in FIG. 14, multiple flexible portions 11 and multiple secondary rigid portions (12B) may be provided. FIG. 14 illustrates an example where two of each the flexible portion 11 and the secondary rigid portion (12B) are provided.

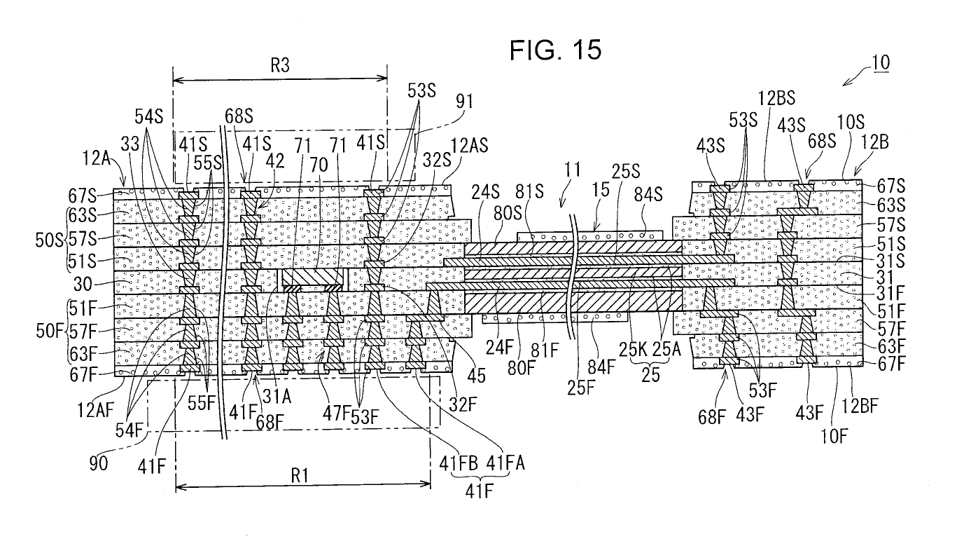

(7) External electrodes 71 may be provided on only one of the surfaces on the front and rear of the electronic component 70 as illustrated in FIG. 15. FIG. 15 illustrates an example of an electronic component 70 with the external electrodes 71 provided on only the first surface (12AF) of the primary rigid portion (12A).

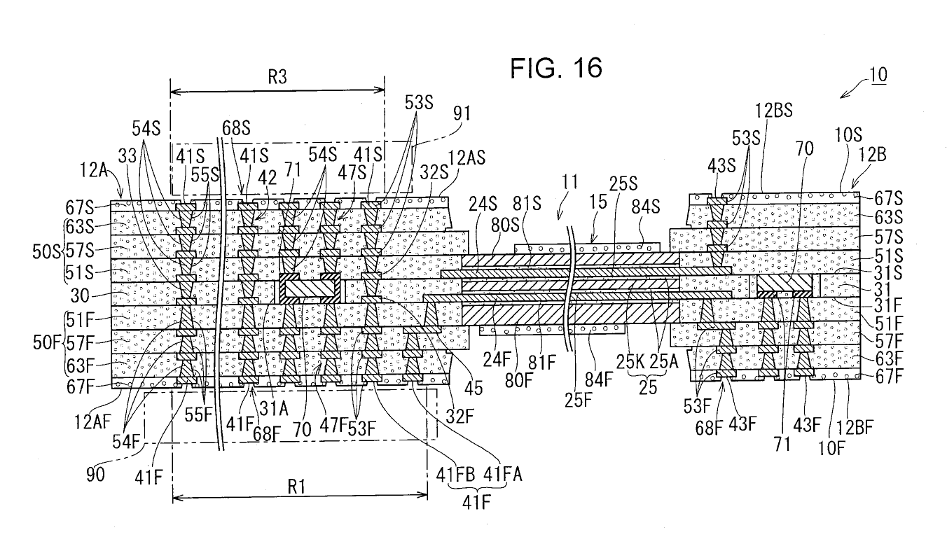

(8) An electronic component 70 may also be embedded in the secondary rigid portion (12B) as illustrated in FIG. 16. In the example illustrated in FIG. 16, the electronic component 70 embedded in the secondary rigid portion (12B) is provided with external electrodes 71 on one of the surfaces on the front and rear thereof similarly to (7) above. However, the external electrodes may be provided on both the front and rear surfaces similarly to the first embodiment.

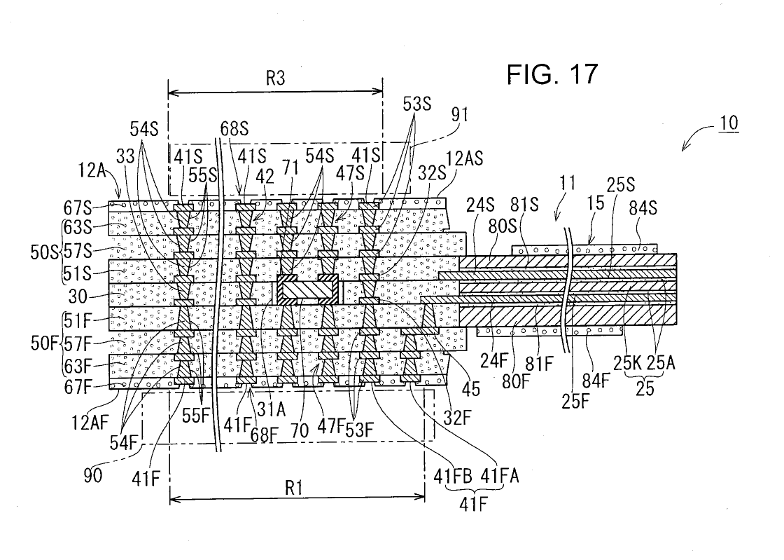

(9) The flex-rigid wiring board 10 according to the first embodiment contains two rigid portions (the primary rigid portion (12A) and the secondary rigid portion (12B)); however, the flex-rigid wiring board 10 may be provided with just a single rigid portion. More specifically, the first embodiment may be provided with only the primary rigid portion (12A) (refer to FIG. 17).

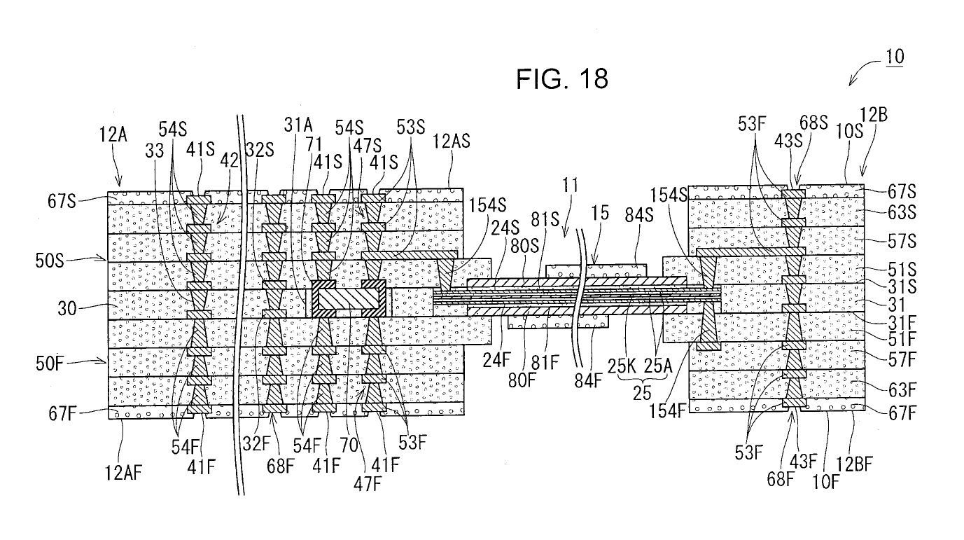

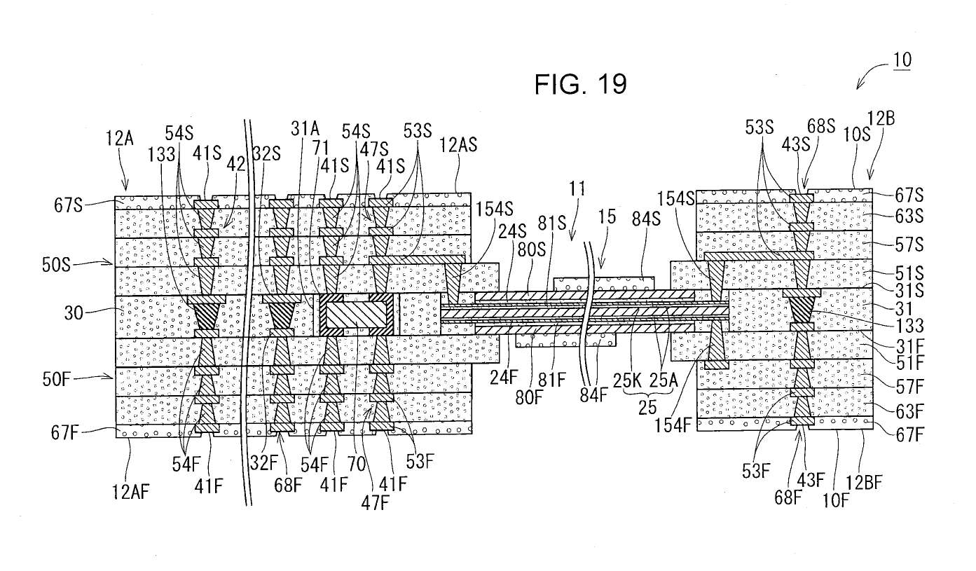

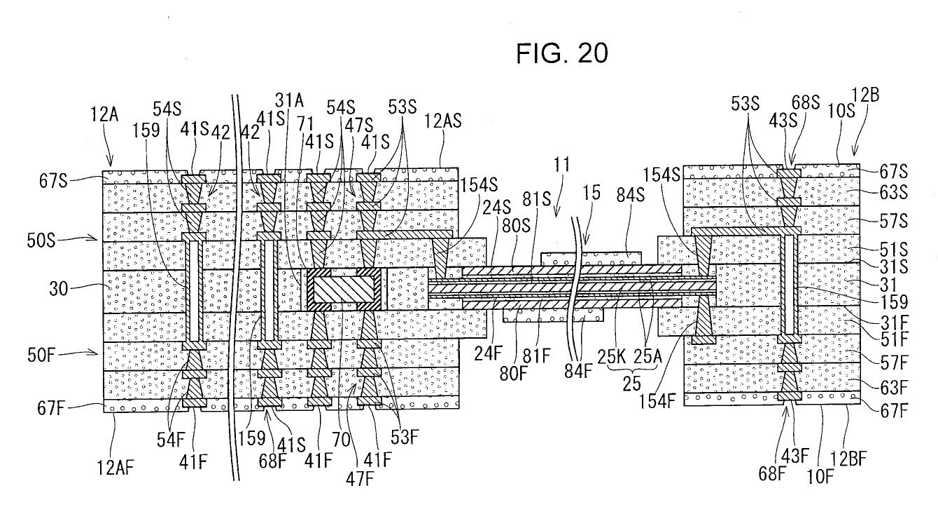

(10) The interconnect linking the primary rigid portion (12A) and the flexible portion 11 is made up of first interconnect layer (24F) spanning over the flexible intermediate base material 25 and over the rigid intermediate base material 31, and the second interconnect layer (24S) in the first embodiment. However, as illustrated in FIG. 18, the first interconnect layer (24F) and the second interconnect layer (24S) may be disposed over only the flexible intermediate base material 25, while the conductive buildup layers (53F, 53S) are extended horizontally to overlap the flexible intermediate base material 25 and conductive vias (154F, 154S) are formed through the insulating buildup layers (51F, 51S) to connect the conductive buildup layers (53F, 53S) with the first interconnect layer (24F) and the second interconnect layer (24S). The structure may be further modified with the below-mentioned kinds of stacked vias 42. Namely, a conductive paste layer 133 may be formed to replace the conductive vias 33, as illustrated in FIG. 19. In addition, the portion of the stacked vias 42 that contain the conductive vias 33 may be a conductive through hole 159 as illustrated in FIG. 20.

A non-bendable insulating buildup layer may be laminated on a portion of a flexible base material where the exposed portion of the flexible base material forms the flexible portion, and the portion on which the insulating buildup layer is laminated forms the rigid portion. An electronic component may also be embedded in the insulating buildup layer.

However, it tends to be difficult to reduce the profile of the above-described flex-rigid wiring board because the insulating buildup layer with embedded electronic component is laminated onto the flexible base material.

A flex-rigid wiring board according to an embodiment of the present invention gives a thinner profile.

A flex-rigid wiring board according to an embodiment of the invention is provided with a flexible portion that is bendable, and a rigid portion that is non-bendable positioned beside the flexible portion and connected to the flexible portion. The flex-rigid wiring board includes a flexible base material; a rigid base material that is positioned beside the flexible base material when viewed from the side; a buildup layer laminated on both the front and rear surfaces of the flexible base material and the rigid base material to form the rigid portion, and the part exposing the flexible base material serving as the flexible portion. An electronic component is embedded in the rigid base material.

Obviously, numerous modifications and variations of the present invention are possible in light of the above teachings. It is therefore to be understood that within the scope of the appended claims, the invention may be practiced otherwise than as specifically described herein.

What is claimed is:

1. A flex-rigid wiring board, comprising:
a flexible base material structure;
a rigid base material structure extending from opposite ends of the flexible base material structure;
an electronic component embedded in the rigid base material structure;
a first buildup layer laminated on first surfaces of the flexible base material structure and rigid base material structure and having an exposing portion exposing the first surface of the flexible base material structure; and
a second buildup layer laminated on second surfaces of the flexible base material structure and rigid base material structure and having an exposing portion exposing the second surface of the flexible base material structure,
wherein the first and second buildup layers are formed such that the flexible base material structure exposed by the exposing portions of the first and second buildup layers forms a bendable portion and that the rigid base material structure and the first and second buildup layers form non-bendable portions connected to the bendable portion.

2. A flex-rigid wiring board according to claim 1, wherein the first buildup layer includes a plurality of first pads, and a stack via structure connecting the electronic component and at least one of the first pads.

3. A flex-rigid wiring board according to claim 2, wherein the second buildup layer includes a plurality of second pads, and a stack via structure connecting the electronic component and at least one of the second pads.

4. A flex-rigid wiring board according to claim 3, further comprising:
a full stack via structure formed through the first buildup layer, the rigid base material structure and the second buildup layer such that the full stack via structure is connecting at least one of the first pads and at least one of the second pads.

5. A flex-rigid wiring board according to claim 4, wherein the non-bendable portions comprise a primary rigid portion on one end of the bendable portion and a secondary rigid portion on an opposite end of the bendable portion, and the first and second pads are formed on the primary rigid portion.

6. A flex-rigid wiring board according to claim 1, wherein the non-bendable portions comprise a primary rigid portion on one end of the bendable portion and a secondary rigid portion on an opposite end of the bendable portion.

7. A flex-rigid wiring board according to claim 1, wherein the first buildup layer includes a plurality of first pads positioned to mount a second electronic component onto the first buildup layer, and a stack via structure connecting the electronic component and at least one of the first pads.

8. A flex-rigid wiring board according to claim 7, wherein the second buildup layer includes a plurality of second pads positioned to mount a third electronic component onto the second buildup layer, and a stack via structure connecting the electronic component and at least one of the second pads.

9. A flex-rigid wiring board according to claim 8, further comprising:
a full stack via structure formed through the first buildup layer, the rigid base material structure and the second buildup layer such that the full stack via structure is connecting at least one of the first pads and at least one of the second pads.

10. A flex-rigid wiring board according to claim 9, wherein the non-bendable portions comprise a primary rigid portion on one end of the bendable portion and a secondary rigid portion on an opposite end of the bendable portion, and the first and second pads are formed on the primary rigid portion.

11. A flex-rigid wiring board according to claim 8, wherein the second electronic component is an active component, and the third electronic component is a passive component.

12. A flex-rigid wiring board according to claim 8, wherein the stack via structure in the first buildup layer comprises a plurality of stack via conductors connecting the electronic component and a group of the first pads, and the stack via structure in the second buildup layer comprises a plurality of stack via conductors connecting the electronic component and a group of the second pads.

13. A flex-rigid wiring board according to claim 1, wherein the flexible base material structure comprises a resin film and an interconnect layer formed on the resin film.

14. A flex-rigid wiring board according to claim 1, wherein the non-bendable portions comprise a primary rigid portion on one end of the bendable portion and a secondary rigid portion on an opposite end of the bendable portion, and the flexible base material structure comprises a resin film and an interconnect layer formed on the resin film such that the interconnect layer connecting the first buildup layer in the primary rigid portion and the first buildup layer in the secondary rigid portion.

15. A flex-rigid wiring board according to claim 1, wherein the first buildup layer comprises a plurality of insulating layers and a plurality of conductive layers, and the second buildup layer comprises a plurality of insulating layers and a plurality of conductive layers.

16. A flex-rigid wiring board according to claim 4, wherein the first buildup layer comprises a plurality of insulating layers and a plurality of conductive layers, and the second buildup layer comprises a plurality of insulating layers and a plurality of conductive layers.

17. A flex-rigid wiring board according to claim 4, wherein the full stack via structure comprises a plurality of full stack via conductors connecting a group of the first pads and a group of the second pads.

18. A flex-rigid wiring board according to claim 9, wherein the first buildup layer comprises a plurality of insulating layers and a plurality of conductive layers, and the second buildup layer comprises a plurality of insulating layers and a plurality of conductive layers.

19. A flex-rigid wiring board according to claim 9, wherein the full stack via structure comprises a plurality of full stack via conductors connecting a group of the first pads and a group of the second pads.

20. A flex-rigid wiring board according to claim 19, wherein the flexible base material structure comprises a resin film and an interconnect layer formed on the resin film.
